(19) United States
(12) Patent Application Publication
(10) Pub. No.: US 2017/0249994 A1
(43) Pub. Date: Aug. 31, 2017

(54) SEMICONDUCTOR MEMORY DEVICE

(71) Applicant: KABUSHIKI KAISHA TOSHIBA, Tokyo (JP)

(72) Inventor: Toshifumi HASHIMOTO, Fujisawa Kanagawa (JP)

(21) Appl. No.: 15/233,691

(22) Filed: Aug. 10, 2016

(30) Foreign Application Priority Data
Feb. 29, 2016 (JP) 2016-037803

(51) Int. Cl. G11C 16/04; G11C 16/08

(52) U.S. Cl. CPC G11C 16/0483; G11C 16/08

(57) ABSTRACT

A semiconductor memory device includes a plurality of string units, including first and second string units in a first block, third and fourth string units in a second block, each of the string units including a plurality of serially connected memory cells between first and second select transistors, and first through fourth select gate lines. The first select gate line is commonly connected to gates of the first select transistors of the first and third string units. The second select gate line is commonly connected to gates of the first select transistors of the second and fourth string units. The third select gate line is commonly connected to gates of the second select transistors of the first and fourth string units. The fourth select gate line is commonly connected to gates of the second select transistors of the second string unit and another string unit.

### CROSS-REFERENCE TO RELATED APPLICATION

This application is based upon and claims the benefit of priority from. Japanese Patent Application No. 2016-037803, filed on Feb. 29, 2016, the entire contents of which are incorporated herein by reference.

### FIELD

Embodiments described herein relate generally to a semiconductor memory device.

### BACKGROUND

A NAND type flash memory in which memory cells are stacked three-dimensionally is known as one type of a semiconductor memory device.

### DESCRIPTION OF THE DRAWINGS

FIG. 1 is a block diagram illustrating a configuration of a semiconductor memory device according to a first embodiment.

FIG. 2 is a circuit diagram illustrating a configuration of a memory cell array of the semiconductor memory device according to the first embodiment.

FIG. 3 is a block diagram illustrating configurations of a row decoder and a peripheral circuit in the semiconductor memory device according to the first embodiment.

FIG. 4 is a circuit diagram illustrating the configurations of the row decoder and the peripheral circuit in the semiconductor memory device according to the first embodiment.

FIG. 5 is a table illustrating an example of block selection which is performed by the row decoder of the semiconductor memory device according to the first embodiment.

FIG. 6 is a circuit diagram illustrating a configuration of a block decoder of the semiconductor memory device according to the first embodiment.

FIG. 7 is a block diagram illustrating configurations of a word line driver and a select gate line driver of the semiconductor memory device according to the first embodiment.

FIG. 8 is a timing chart illustrating potential changes of various wires at the time of a program operation of data of the semiconductor memory device according to the first embodiment.

FIG. 9 is a timing chart illustrating potential changes of various wires at the time of a read operation of data of the semiconductor memory device according to the first embodiment.

FIG. 10 is a timing chart illustrating potential changes of various wires at the time of an erasure operation of data of the semiconductor memory device according to the first embodiment.

FIG. 11 is a block diagram illustrating configurations of a row decoder and a peripheral circuit in a semiconductor memory device according to a second embodiment.

FIG. 12 is a circuit diagram illustrating the configurations of the row decoder and the peripheral circuit in the semiconductor memory device according to the second embodiment.

FIG. 13 is a table illustrating an example of block selection which is performed by the row decoder of the semiconductor memory device according to the second embodiment.

FIG. 14 is a circuit diagram illustrating a configuration of a block decoder of the semiconductor memory device according to the second embodiment.

FIG. 15 is a block diagram illustrating a configuration of a word line driver and a select gate line driver of the semiconductor memory device according to the second embodiment.

FIG. 16 is a timing chart illustrating potential changes of various wires at the time of a program operation of data of a semiconductor memory device according to a modification example of the first embodiment.

### DETAILED DESCRIPTION

In general, according to one embodiment, a semiconductor memory device includes first and second string units in a first block, third and fourth string units in a second block, each of the string units including a plurality of serially connected memory cells between first and second select transistors, and first through fourth select gate lines. The first select gate line is commonly connected to gates of the first select transistors of the first and third string units. The second select gate line is commonly connected to gates of the first select transistors of the second and fourth string units. The third select gate line is commonly connected to gates of the second select transistors of the first and fourth string units. The fourth select gate line is commonly connected to gates of the second select transistors of the second string unit and another string unit.

Hereinafter, embodiments will be described with reference to the accompanying drawings. In the following description, the same symbols or reference numerals will be attached to elements having the same functions and configurations. In addition, in a case where multiple elements having common reference symbols or reference numerals need to be distinguished, subscripts will be attached to the common reference symbols or reference numerals. In a case where there is no need to distinguish the multiple elements, only the common reference symbols or reference numerals will be used, and the subscripts will not be used.

### 1. First Embodiment

A semiconductor memory device according to a first embodiment will be described.

### 1.1 Configuration

### 1.1.1 Configuration of Semiconductor Memory Device

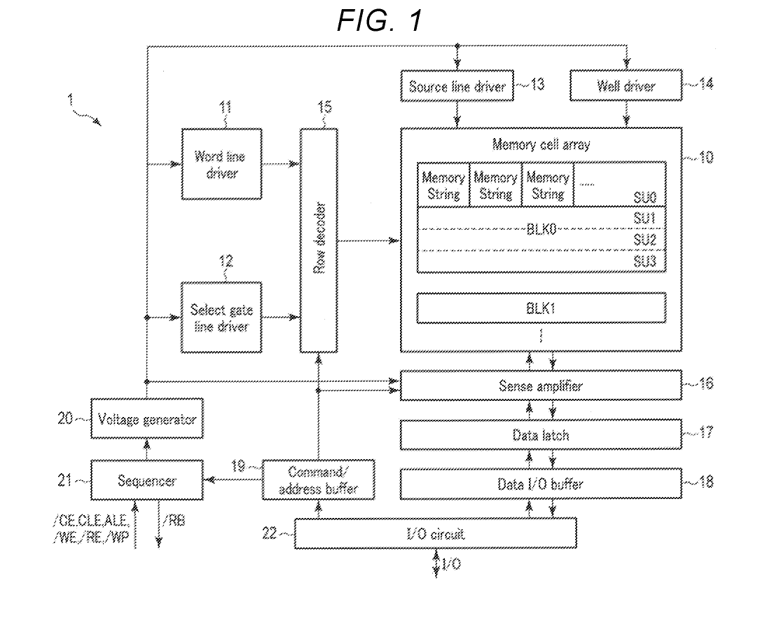

A configuration example of the semiconductor memory device according to the first embodiment will be described with reference to FIG. 1. FIG. 1 is a block diagram illustrating a configuration of the semiconductor memory device according to the first embodiment.

A semiconductor memory device 1 includes a memory cell array 10, a word line driver 11, a select gate line driver 12, a source line driver 13, a well driver 14, a row decoder 15, a sense amplifier 16, a data latch 17, a data I/O buffer 18, a command/address buffer 19, a voltage generator 20, a sequencer 21, and an I/O circuit 22.

The memory cell array 10 includes multiple blocks BLK (BLK0, BLK1, . . . ) each of which is a set of multiple nonvolatile memory cell transistors (not illustrated) that are each connected to a word line and a bit line. Each block BLK is, for example, an erasure unit, and data in the same block is simultaneously erased. Each of the blocks BLK includes multiple string units SU (SU0, SU1, SU2, . . . ). Each string unit SU is a set of memory strings MS. Each of the memory strings MS includes multiple memory cell transistors.

The number of blocks in the memory cell array 10, the number of string units in one block BLK, and the number of memory strings in one string unit SU can be arbitrarily set. In the present embodiment, it is assumed that the block BLK0 includes four string units SU0 to SU3. In addition, it is assumed that each of the other blocks BLK has the same configuration as the block BLK0.

The voltage generator 20 generates voltages required for an operation of writing, reading, erasing, and the like of data, based on instructions from, for example, the sequencer 21. The voltage generator 20 supplies the generated voltages to the word line driver 11, the select gate line driver 12, the source line driver 13, the well driver 14, and the sense amplifier 16.

The word line driver 11 applies required voltages to a selected word line and unselected word lines through the row decoder 15. The select gate line driver 12 applies required voltages to a selected select gate line and unselected select gate lines SGDL and SGSL through the row decoder 15.

The source line driver 13 applies a required voltage to a source line. The well driver 14 applies a voltage to a well region. The well region is connected to a semiconductor region of each of the memory strings MS, and in a case where a transistor in the semiconductor region is turned on, a channel is formed in the semiconductor region.

The row decoder 15 receives voltages required for an operation from the word line driver 11 and the select gate line driver 12. In addition, the row decoder 15 decodes a block address or a page address, based on a block address signal which is received from the command/address buffer 19. The row decoder 15 transfers voltages from the word line driver 11 and the select gate line driver 12 to anyone of blocks in the memory cell array 10, based on the decoded result. The row decoder 15 will be described in detail below.

The sense amplifier 16 senses read data through a bit line connected to a memory cell transistor, when reading data stored in the memory cell transistor. The sense amplifier 16 transfers write data through a bit line connected to a memory cell transistor, when writing data in the memory cell transistor. The data latch 17 retains the read data which is sensed by the sense amplifier 16 and the write data which is to be written in the memory cell transistor.

The data I/O buffer 18 retains the write data which is input from the I/O circuit 22, and transfers the write data to the data latch 17. In addition, the data I/O buffer 18 retains and outputs the read data from the data latch 17 to the I/O circuit 22. The command/address buffer 19 retains a command and an address which are received from the I/O circuit 22. The command/address buffer 19 transfers a retained address to the row decoder 15 and the sense amplifier 16, and transfers a retained command to the sequencer 21.

The I/O circuit 22 transfers and receives a signal I/O to and from the outside of the semiconductor memory device 1. The signal I/O has a width of eight bits, in one example, and includes a command, read data or write data, an address, and the like. The I/O circuit 22 outputs the write data to the data I/O buffer 18, and outputs the command and the address to the command/address buffer 19.

The sequencer 21 receives commands which instructs reading, writing, erasing, or the like, from the command/address buffer 19, and receives signals /CE, CLE, ALE, /WE, /RE, and /WP from the outside of the semiconductor memory device 1 through a logic circuit which is not illustrated. The sequencer 21 controls the operation of the semiconductor memory device 1, based on an instruction of the received command, and the respective signals /CE, CLE, ALE, /WE, /RE, and /WP. In addition, the sequencer 21 generates a signal /RB, which is a notification to the outside of a state of the semiconductor memory device 1.

The signal /CE enables the semiconductor memory device 1. The signals CLE and ALE notify the semiconductor memory device 1 that the signals I/O flowing through the semiconductor memory device 1 in parallel with the signal CLE and ALE are respectively a command and an address. The signal /WE instructs the semiconductor memory device 1 to intake the signal I/O to flow through the semiconductor memory device 1 in parallel with the signal /WE. The signal /RE instructs the semiconductor memory device 1 to output the signal I/O. The signal /RB indicates whether the semiconductor memory device 1 is in a ready state (state where it can receive a command from the outside) or a busy state (state where it cannot receive a command from the outside).

### 1.1.2 Configuration of Memory Cell Array

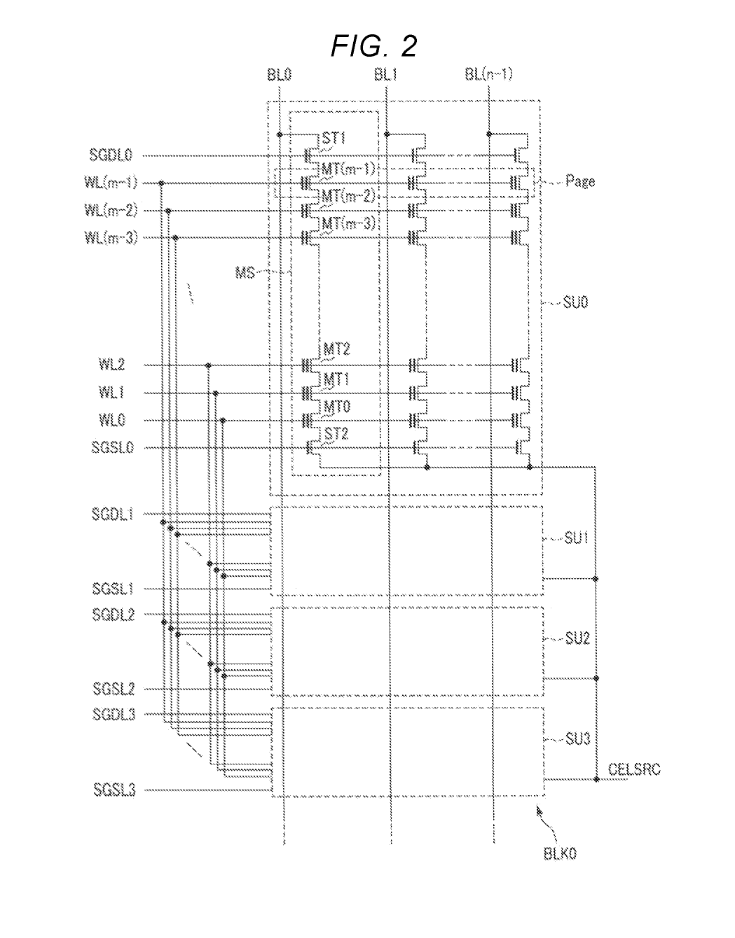

Next, a configuration of the memory cell array 10 of the semiconductor memory device according to the first embodiment will be described with reference to FIG. 2. FIG. 2 is a circuit diagram illustrating a configuration of the memory cell array 10 of the semiconductor memory device 1 according to the first embodiment. FIG. 2 illustrates the block BLK0.

As illustrated in FIG. 2, each of the memory strings MS includes, for example, m (m is a natural number) memory cell transistors MT (MT0 to MT(m−1)), a select transistor ST1, and a select transistor ST2. The memory cell transistor MT includes a stack gate having a control gate and a charge storage layer. The respective memory cell transistors MT are connected in series between the select transistor ST1 and the select transistor ST2. A “connection” as used herein means electrical connections, where another conductive element may be located between “connected” units.

In the block BLK0, gates of the select transistors ST1 in the string units SU0 to SU3 are respectively connected to the select gate lines SGDL0 to SGDL3. In addition, gates of the select transistors ST2 in the string units SU0 to SU3 are respectively connected to the select gate lines SGSL0 to SGSL3. Control gates of the memory cell transistors MT0 to MT(m−1) in the same block BLK0 are respectively connected to the word lines WL0 to WL(m−1). That is, each of the word lines WL0 to WL(m−1) is connected to all the string units SU0 to SU3 in the same block BLK0, and in contrast to this, each of the select gate lines SGDL0 to SGDL3 and the select gate lines SGSL0 to SGSL3 is connected to only one of the string units SU0 to SU3 in the same block BLK0.

In addition, the other terminals of the select transistors ST1 of the memory strings MS in the same column, among the memory strings MS which are arranged in a matrix in the memory cell array 10, are connected to one of n bit lines BL (BL0 to BL (n−1) (n is a natural number)). In addition, the bit lines BL are connected in common to the memory strings MS in the same column, across multiple blocks BLK.

In addition, the other terminals of the select transistors ST2 are connected to a source line CELSRC. The source line CELSRC is connected in common to the multiple memory strings MS across multiple blocks BLK.

As described above, erasing of data is simultaneously performed with respect to the memory cell transistors MT in the same block BLK. In contrast to this, reading and writing of the data are simultaneously performed with respect to the multiple memory cell transistors MT which are connected in common to any one word line WL of any one string unit SU of any one block BLK. A unit which is read or written in this way is called “page”.

The memory cell array 10 may have the configurations described in U.S. Patent Application Publication No. 2009/0267128, U.S. Patent Application Publication No. 2009/0268522, U.S. Patent Application Publication No. 2010/0207195, and U.S. Patent Application Publication No. 2011/0284946. All of these patent applications are incorporated by reference herein in their entirety.

### 1.1.3 Configuration of Row Decoder and Peripheral Circuit

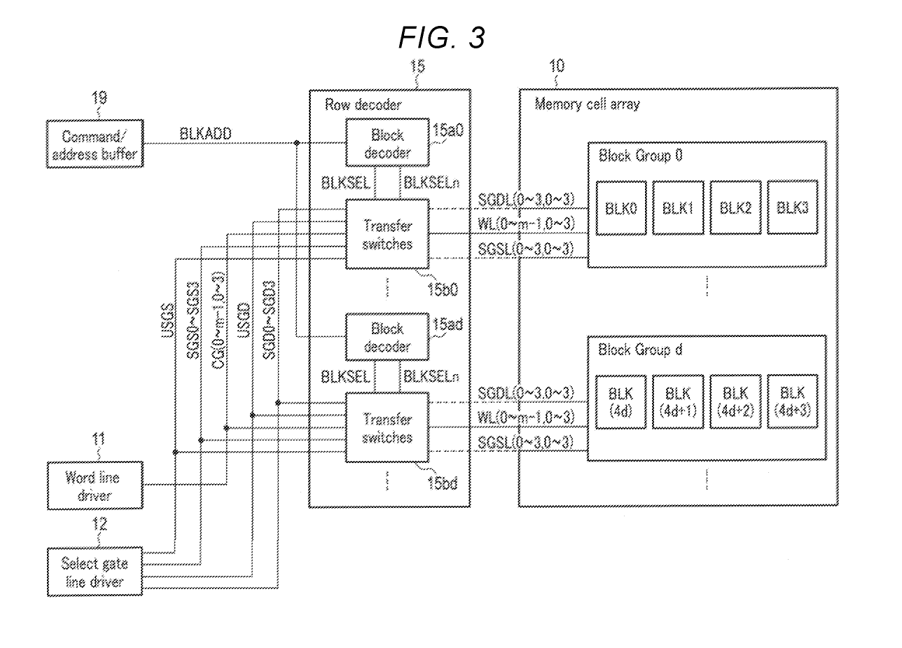

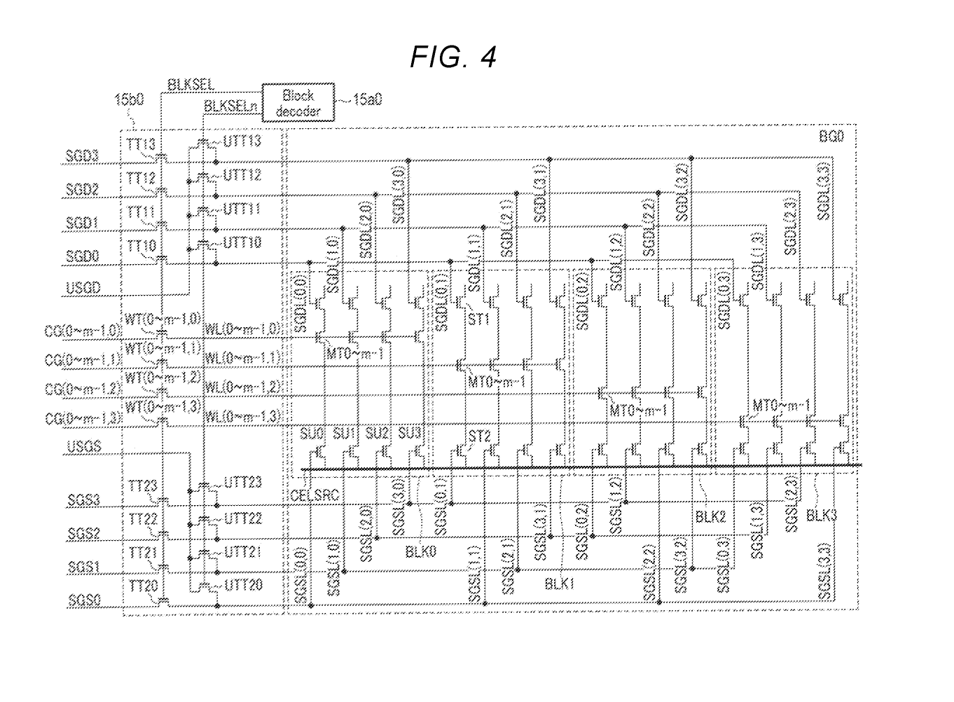

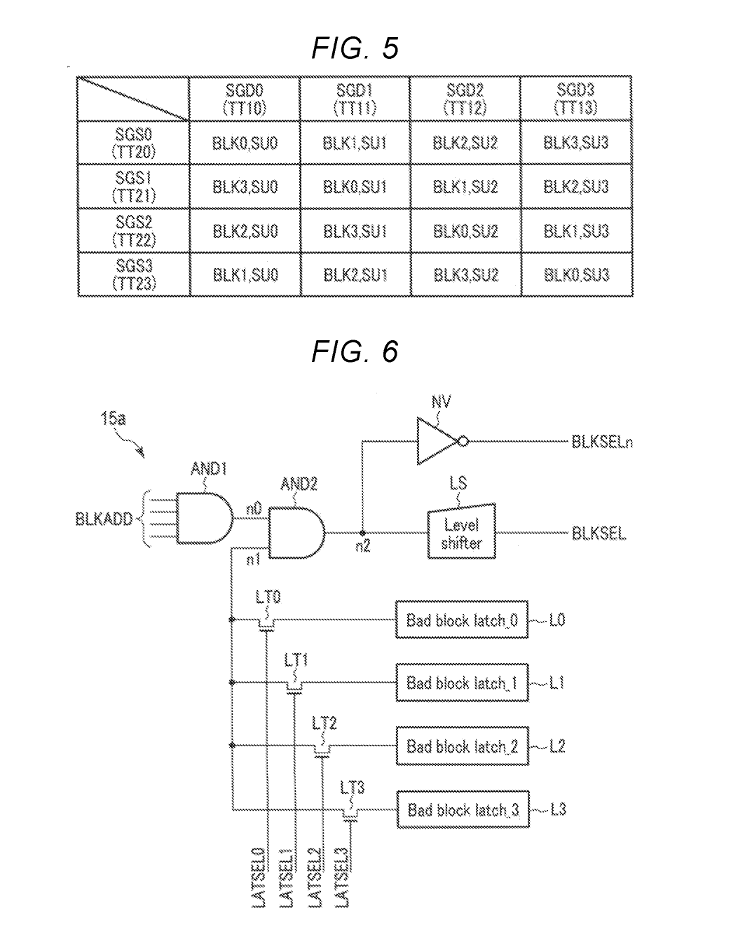

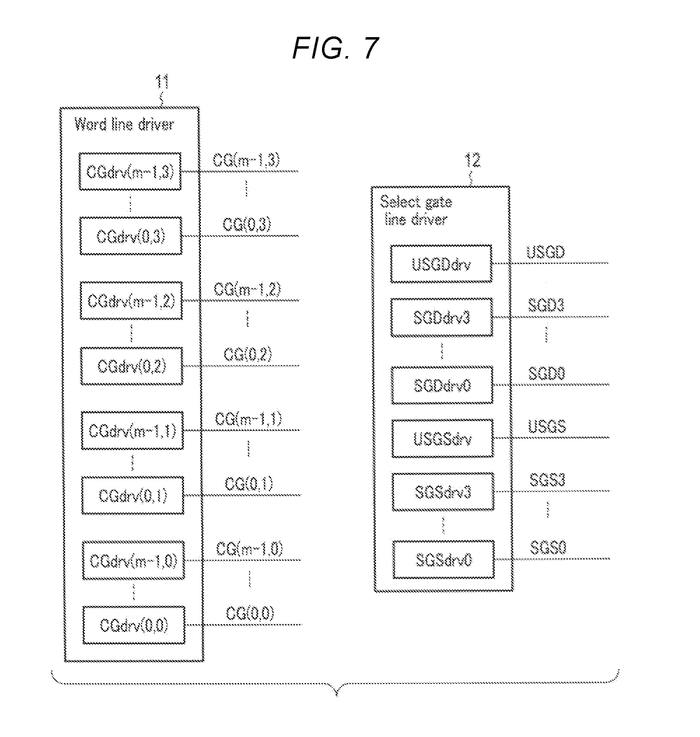

Next, a configuration a row decoder and a peripheral circuit of the semiconductor memory device according to the first embodiment will be described with reference to FIG. 3 to FIG. 7. FIG. 3 is a block diagram illustrating configurations of the row decoder 15 and the peripheral circuit in the semiconductor memory device 1 according to the first embodiment. FIG. 4 is a circuit diagram illustrating the configurations of the row decoder 15 and the peripheral circuit in the semiconductor memory device 1 according to the first embodiment. FIG. 5 is a table illustrating an example of block selection which is performed by the row decoder 15 of the semiconductor memory device 1 according to the first embodiment. FIG. 6 is a circuit diagram illustrating a configuration of a block decoder 15a of the semiconductor memory device 1 according to the first embodiment. FIG. 7 is a block diagram illustrating a configuration of a word line driver 11 and a select gate line driver 12 of the semiconductor memory device 1 according to the first embodiment.

As illustrated in FIG. 3, the row decoder 15 includes multiple block decoders 15a (15a0, . . . , 15ad, . . . ) and multiple transfer switch groups 15b (15b0, . . . , 15bd, . . . ) (d is a natural number). The block decoders 15a and each of the transfer switch groups 15b are respectively assigned to block groups BG (BG0, . . . , BGd, . . . ) which includes the multiple blocks BLK in the memory cell array 10.

In the example of FIG. 3, each of the block groups BG includes four blocks BLK. That is, the block decoder 15ad and the transfer switch group 15bd are shared by multiple blocks BLK4d to BLK(4d+3) in the block group BGd. The number of blocks in the block group BG is not limited to four, and may be any natural number. However, the first embodiment requires that the number of blocks in each of the block groups BG is equal to or less than the number of the string units which are included in each of the blocks BLK.

Each of the block decoders 15a receives a block address signal BLKADD from the command/address buffer 19. The block address signal BLKADD specifies one block BLK. A block group BG in which the specified block BLK is included is specified by the block address signal BLKADD, and the block decoder 15a corresponding to the specified block group BG is specified. That is, one block decoder 15a is selected by the block address signal BLKADD. The block decoder 15a selected based on the block address signal BLKADD outputs a block group select signal BLKSEL to the transfer switch group 15b. Meanwhile, the unselected block decoders 15a output a block group non-select signal BLKSELn to the transfer switch group 15b.

Each of the transfer switch groups 15b is connected to the word line driver 11 and the select gate line driver 12 by multiple wires. More specifically, each terminal of the transfer switch groups 15b is connected in common to the word line driver 11 through the same wires CG (0 to m−1, and 0 to 3). In addition, each terminal of the transfer switch groups 15b is connected in common to the select gate line driver 12 through the same wires USGD, USGS, SGD (SGD0 to SGD3), and SGS (SGS0 to SGS3). In addition, the other terminals of the transfer switch groups 15b are respectively connected to the corresponding block group BG through the select gate lines SGDL (0 to 3, 0 to 3), SGSL (0 to 3, 0 to 3), and the word lines WL (0 to m−1, 0 to 3). By connecting in this manner, each of the transfer switch groups 15b transfers all the voltages which are applied to the transfer switch group 15b by the word line driver 11 and the select gate line driver 12, to each of the corresponding block groups BG, in response to the block group select signal BLKSEL or the block group non-select signal BLKSELn.

Here, subscripts (i, k) (0≦i≦3) (0≦k≦3) attached to the select gate lines SGDL and SGSL indicate that the select gate lines correspond to an ith string unit SUi in a kth block BLKk in the block group BG including the select gate lines SGDL and SGSL. Subscripts (j, k) (0≦j≦m−1) attached to the wire CG, the word line WL, and a transfer transistor (not illustrated) indicate that the wire, the word line, and the transfer transistor correspond to a jth memory cell transistor MTj in the memory string MS in the kth block BLKk in the block group BG including the wire CG and the word line WL. In addition, for example, the wires CG (0 to 3, 0 to 3) indicate the wires CG (0,0), CG (0,1), CG (0,2), CG (0,3), CG (1,0), CG (1,1), CG (1,2), CG (1,3), CG (2,0), CG (2,1), CG (2,2), CG (2,3), CG (3,0), CG (3,1), CG (3,2), and CG (3,3). These are applied to other subscripts attached to each configuration element in the same manner, in the following description.

A connection example of the block decoder 15a0, the transfer switch group 15b0, and a peripheral circuit is illustrated in FIG. 4 as a more specific example. As illustrated in FIG. 4, the transfer switch group 15b0 includes four transfer transistors TT1 (TT10 to TT13), 4m transfer transistors WT (0 to m−1, 0 to 3), and four transfer transistor TT2 (TT20 to TT23), as transfer transistor for selecting the block group BG0. In addition, the transfer switch group 15b0 includes four transfer transistors UTT1 (UTT10 to UTT13), and four transfer transistor UTT2 (UTT20 to UTT23), as transfer transistor for unselecting the block group BG0. That is, the transfer switch groups 15b corresponding to a certain block group BG according to the first embodiment includes (4m+16) transfer transistors.

Each gate of the transfer transistors TT1, WT, and TT2 receives in common the block group select signal BLKSEL from the block decoder 15a0. That is, the transfer transistors TT1, WT, and TT2 are turned on in a case where the block group select signal BLKSEL goes to an “H (high)” level, and are turned off in a case where the block group select signal BLKSEL goes to an “L (low)” level.

In addition, each gate of the transfer transistors UTT1 and UTT2 receives in common the block group select signal BLKSELn from the block decoder 15a0. That is, the transfer transistors UTT1, and UTT2 are turned on in a case where the block group select signal BLKSELn goes to an “H” level, and are turned off in a case where the block group select signal BLKSELn goes to an “L” level.

The word lines WL (0 to m−1, 0 to 3) are connected to each of the wires CG (0 to m−1, 0 to 3) through each of the transfer transistors WT (0 to m−1, 0 to 3).

One terminal of the select gate line SGDL (i, k) is connected to the select transistor ST1 of the string unit SUi of the block BLKk. In addition, the other terminal of the select gate line SGDL is connected to the wire SGD through the transfer transistor TT1. More specifically, for example, each of the other terminals of the four select gate lines SGDL (i, 0 to 3) is connected the wire SGDi through the transfer transistor TT1i.

The other terminals of the select gate lines SGDL (i, 0 to 3) are connected in common to a wire USGD through each of the transfer transistors UTT10 to UTT13.

One terminal of the select gate lines SGSL (i, k) is connected to the select transistor ST2 of the string unit SUi of the block BLKk. In addition, the other terminal of the select gate line SGSL is connected to the wire SGS through the transfer transistor TT2. Specifically, the other terminals of each of, for example, the four select gate lines SGSL (0, 0), SGSL (1, 1), SGSL (2, 2), and SGSL (3, 3) (hereinafter, referred to as “zeroth set of select gate lines SGSL”) are connected in common to the wire SGS0 through the transfer transistor TT20. The other terminals of each of the four select gate lines SGSL (1, 0), SGSL (2, 1), SGSL (3, 2), and SGSL (0, 3) (hereinafter, referred to as “first set of select gate lines SGSL”) are connected in common to the wire SGS1 through the transfer transistor TT21. The other terminals of each of the four select gate lines SGSL (2, 0), SGSL (3, 1), SGSL (0, 2), and SGSL (1, 3) (hereinafter, referred to as “second set of select gate lines SGSL”) are connected in common to the wire SGS2 through the transfer transistor TT22. The other terminals of each of the four select gate lines SGSL (3, 0), SGSL (0, 1), SGSL (1, 2), and SGSL (2, 3) (hereinafter, referred to as “third set of select gate lines SGSL”) are connected in common to the wire SGS3 through the transfer transistor TT23.

The zeroth to third sets of the select gate lines SGSL are connected in common to the wire USGS through each of the transfer transistors UTT20 to UTT23.

That is, the wires CG, SGD, SGS, USGD, and USGS include (4m+10) wires.

In conclusion, a set of one wire SGD and one wire SGS uniquely selects one string unit SU in the block group BG, as illustrated in FIG. 5. A set of one wire SGD and one wire SGS corresponds to a set of one transfer transistor TT1 and one transfer transistor TT2.

In addition, from another point of view, the connection relationship between each of string unit SU of the block BLK and the wires SGD and SGS in the block group BG0 can be described as follows.

The string units SU0 to SU3 in the block BLK0 are respectively selected by a set of the wires SGD0 and SGS0, a set of the wires SGD1 and SGS1, a set of the wires SGD2 and SGS2, and a set of the wires SGD3 and SGS3.

The string units SU0 to SU3 in the block BLK1 are respectively selected by a set of the wires SGD0 and SGS3, a set of the wires SGD1 and SGS0, a set of the wires SGD2 and SGS1, and a set of the wires SGD3 and SGS2.

The string units SU0 to SU3 in the block BLK2 are respectively selected by a set of the wires SGD0 and SGS2, a set of the wires SGD1 and SGS3, a set of the wires SGD2 and SGS0, and a set of the wires SGD3 and SGS1.

The string units SU0 to SU3 in the block BLK3 are respectively selected by a set of the wires SGD0 and SGS1, a set of the wires SGD1 and SGS2, a set of the wires SGD2 and SGS3, and a set of the wires SGD3 and SGS0.

By the above configuration, voltages which are applied to the set of one wire SGD and one wire SGS are respectively transferred to gates of the select transistors ST1 and ST2 of one selected string unit SU in the selected block group BG. In addition, voltages which are applied to the wires CG are respectively transferred to the word lines WL in the selected block group BG, and then, are respectively transferred to the control gates of the memory cell transistors MT.

Next, a configuration of the block decoder of the semiconductor memory device according to the first embodiment will be described with reference to FIG. 6. As illustrated in FIG. 6, the block decoder 15a includes logical product circuits AND1 and AND2, bad block latches L (L0 to L3), an inverter NV, a level shifter LS, and latch select transistors LT (LT0 to LT3).

The logical product circuit AND1 receives the block address signal BLKADD from the command/address buffer 19 and outputs a logical product result thereof to a node n0. In the block decoder 15a which receives an input of the block address signal BLKADD, the logical product circuit AND1 outputs an “H” level to the node n0. The logical product circuit AND2 receives voltages of the node n0 and a node n1 and outputs a logical product result thereof to a node n2. That is, the logical product circuit AND2 outputs an “H” level to the node n2, in a case where the voltages of both the nodes n0 and n1 are in an “H” level. The level shifter LS receives a voltage of the node n2. The level shifter LS changes the received voltage to an appropriate voltage, and outputs the changed voltage to the block decoder 15a as the block group select signal BLKSEL. The inverter NV receives a voltage of the node n2. The inverter NV inverts the received voltage and outputs the inverted voltage to the transfer switch group 15b as the block group select signal BLKSELn.

The bad block latches L are provided so as to correspond to the blocks BLK. The bad block latches L can receive a determination signal on whether or not the corresponding block BLK is bad, and in addition, can retain the determination signal. For example, the bad block latches L retain an “L” level, in a case where the blocks BLK fail, and retain an “H” level, in a case where the blocks BLK are normal. The determination signal is input to each of the bad block latches L, when a power supply of the semiconductor memory device 1 is switched on. In addition, for example, an output signal is continuously output until a determination signal with another result is newly input.

One terminal of each of the latch select transistors LT0 to LT3 is connected to each of output terminals of the bad block latches L0 to L3. The other terminals of the latch select transistors LT are connected in common to the node n1. The latch select transistors LT0 to LT3 are respectively turned on or off by receiving latch select signals LATSEL (LATSEL0 to LATSEL3) to gates thereof.

The latch select signals LATSEL are input from, for example, the sequencer 21. The latch select signals LATSEL turn on the latch select transistors LT which are connected to the bad block latches L corresponding to the selected block BLK. In addition, the latch select signals LATSEL turn off the latch select transistors LT which are connected to the bad block latches L corresponding to the unselected block BLK. That is, a voltage of the node n1 goes to an “H” level in a case where the selected block is normal, and goes to an “L” level in a case where the selected block is abnormal.

In a case where each block BLK fails, the sequencer 21 may perform a different control operation according to whether the failure is a (local) failure which affects only an independent block BLK or is a (global) failure which affects all the blocks BLK in the block group BG.

For example, it is assumed that the local failure indicates a failure of an independent configuration element such as a memory cell transistor MT in the block BLK. For example, it is assumed that the global failure indicates a failure of any one of the transfer transistors TT1 and TT2 which are shared between each block BLK in the same block group BG. In a case where the global failure is generated, there is a possibility that an appropriate voltage is not supplied to a selected block BLK, even though the selected block BLK is normal.

Thus, in a case of a global failure, the sequencer 21 can treat the block group BG in which the block BLK is involved, as a failure, even though the selected block BLK does not fail. More specifically, for example, in a case of the global failure, the sequencer 21 retains an “L” level in at least one of the bad block latches L, regardless of a state of the corresponding block BLK. In addition, the sequencer 21 always turns on the latch select transistor LT connected to the bad block latch L which retains an “L” level. By the control operation, an “L” level is retained in the node n1 at all times, and thus, it is possible to prevent the block group select signal BLKSEL from outputting to the block group BG in which the global failure is generated.

Next, configurations of the word line driver and the select gate line driver of the semiconductor memory device according to the first embodiment will be described with reference to FIG. 7. As illustrated in FIG. 7, the word line driver 11 includes drivers CGdrv (0 to m−1, 0 to 3). The select gate line driver 12 includes drivers SGDdrv (SGDdrv0 to SGDdrv3), SGSdrv (SGSdrv0 to SGSdrv3), USGDdrv, and USGSdrv. The drivers CGdrv, SGDdrv, SGSdrv, USGDdrv, and USGSdrv can respectively and independently output voltages.

The drivers CGdrv (0 to m−1, 0 to 3) are respectively connected to the wires CG (0 to m−1, 0 to 3). The drivers SGDdrv0 to SGDdrv3 are respectively connected to the wires SGD0 to SGD3. The drivers SGSdrv0 to SGSdrv3 are respectively connected to the wires SGS0 to SGS3. The driver USGDdrv is connected to the wire USGD. The driver USGSdrv is connected to the wire USGS. By connecting in this manner, independent voltages can be applied to each of total (4m+10) wires CG, SGD, SGS, USGD, and USGS.

### 1.2 Operation

Next, a write operation and an erasure operation of data of the semiconductor memory device according to the first embodiment will be described hereinafter. The operations described below are performed by control of the sequencer 21.

### 1.2.1 Write Operation

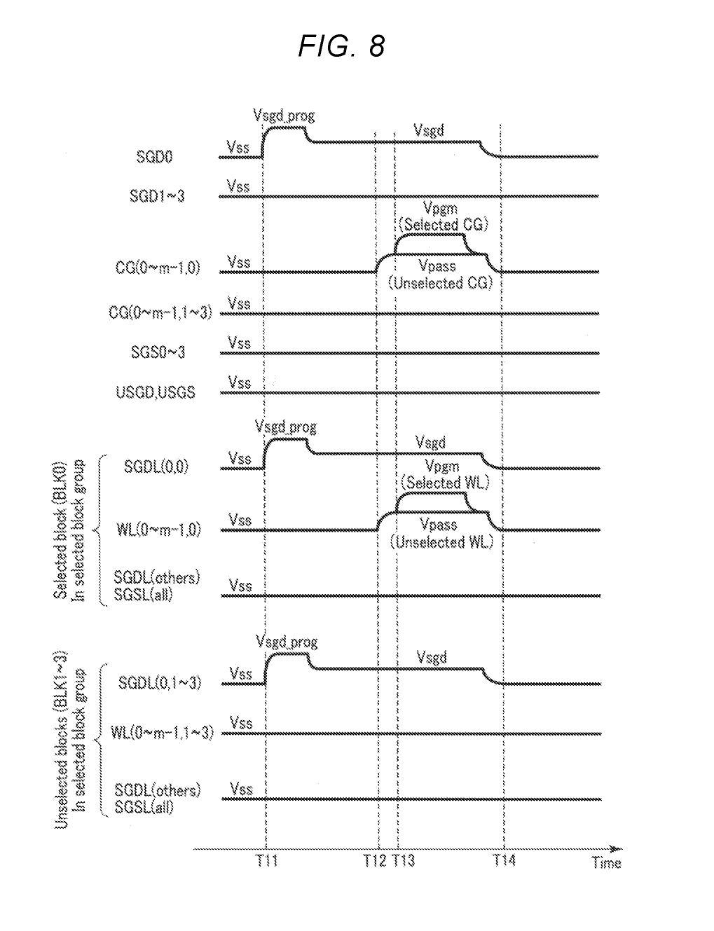

First, the write operation of data of the semiconductor memory device according to the first embodiment will be described with reference to FIG. 8. FIG. 8 is a timing chart illustrating potential changes of various wires at the time of a program operation of the semiconductor memory device 1 according to the first embodiment. In the following description, a case where the string unit SU0 in the block BLK0 in the block group BG0 is selected and data is written to a certain page of the selected string unit SU0 will be described. That is, as illustrated in FIG. 5, a set of the wire SGD0 and the wire SGS0, and a set of the transfer transistor TT10 and the transfer transistor TT20 uniquely correspond to the selected string unit SU. The write operation of data includes a program operation and a program verification operation. To begin with, the program operation will be described with reference to FIG. 8.

Until reaching a point in time T11, the block decoder 15a0 corresponding to the block group BG0 outputs the block group select signal BLKSEL. That is, the transfer transistors TT1, WT, and TT2 in the transfer switch group 15b0 corresponding to the selected block group BG0 are in an ON state.

In addition, the block decoder 15a corresponding to the unselected block group BG outputs the block group non-select signal BLKSELn. That is, the transfer transistors UTT1 and UTT2 in the transfer switch group 15b corresponding to the unselected block groups BG are turned on. The select gate line driver 12 applies a potential Vss (for example, 0 V) to the wires USGD and USGS. Hence, in the subsequent operation, all the transfer transistors ST1 and ST2 in the unselected block group BG are turned off.

At the point in time T11, the select gate line driver 12 applies a potential Vsgd_prog to the wire SGD0, and then drops the potential Vsgd_prog to a potential Vsgd (for example, 3.5 V). That is, the potential Vsgd_prog and the potential Vsgd are applied to the select gate lines SGDL (0, 0 to 3) through the transfer transistor TT10. Thus, the select transistor ST1 of the string unit SU0 in each of the blocks BLK0 to BLK3 is turned on. In addition, the select gate line driver 12 applies the potential Vss to the wires SGD1 to SGD3. That is, the potential Vss is applied to a set of the select gate lines SGDL (1, 0 to 3), a set of the select gate lines SGDL (2, 0 to 3), and a set of the select gate lines SGDL (3, 0 to 2) through each of transfer transistors TT11 to TT13. That is, the select transistors ST1 of the string units SU1 to SU3 in each of the blocks BLK0 to BLK3 are turned off.

In addition, the select gate line driver 12 continuously applies the potential Vss to the wires SGS0 to SGS3 during the program operation from a point in time T11 to a point in time T14. That is, the potential Vss is applies to all the select gate lines SGSL (0 to 3, 0 to 3) through the transfer transistors TT20 to TT23. Thus, all the select transistors ST2 in the block group BG0 are retained in an off state.

At the point in time T11, the word line driver 11 applies the potential Vss to all the wires CG.

As a point in time T12, the word line driver 11 applies a potential Vpass to the wires CG (0 to m−1, 0). That is, the potential Vpass is applied to the word lines WL (0 to m−1, 0). The word line driver 11 raises a potential of the wires CG (p, 0) corresponding to the selected word line WL (p, 0) connected to a page which is a program target, among the wires CG (0 to m−1, 0), to a program potential Vpgm, at a point in time T13. Meanwhile, the word line driver 11 maintains the potentials of the wires CG (0 to m−1 (≠p), 0) as the potential Vpass. That is, the write voltage Vpgm is applied to the selected word line WL, and the potential Vpass is applied to the unselected word line WL.

The program potential Vpgm is a potential for injecting electric charges into a charge storage layer, and is higher than the potential Vpass. The potential Vpass is higher than the potential Vss, and has a magnitude which prevents erroneous writing to unselected memory cell transistors MT in the memory string MS which is a program target. In addition, the potential Vpass has a magnitude which can raise a channel potential by coupling, to the extent that a threshold voltage of the selected memory cell transistor MT is prevented from increasing, in the memory string MS which is not a program target. The memory string MS which is a program target is the memory string MS which is connected the bit line BL to which a low potential (for example, potential Vss) is applied. The memory string MS which is not a program target is the memory string MS which is connected to the bit line BL to which a high potential (for example, potential Vpre>potential Vss) is applied. The word line driver 11 applies the potential Vss to the wires CG (0 to m−1, 1 to 3) corresponding to the unselected block BLK.

As the program potential Vpgm is applied to the wire CG (p, 0), the program potential Vpgm is applied to the word line WL (p, 0) which is connected to the block BLK0. Hence, only a memory cell transistors MTp of the string unit SU0 which is in a state where the select transistor ST1 in the block BLK0 can be programmed. That is, the memory cell transistors MT are programmed in the memory string MS which is a program target, and are not programmed in each memory string MS which is not a program target. Meanwhile, the string units SU0 in the unselected blocks BLK1 to BLK3 are also connected to the bit lines BL in the same manner as the string unit SU0 of the selected block BLK0, but are not programmed. As described above, the potential Vss is applied to the wires CG (0 to m−1, 1 to 3) corresponding to each of the unselected blocks BLK1 to BLK3.

Thereafter, the word line driver 11 applies the potential Vss to all the wires CG, and then stops the program operation.

In this way, the wire SGD corresponding to the selected string unit SU is selected, and the program potential Vpgm or the potential Vpass is applied to only the wire CG corresponding to the selected block BLK.

Next, the sequencer 21 performs a program verification operation. The program verification operation can be performed in the same manner as a read operation which will be described below.

### 1.2.2 Read Operation

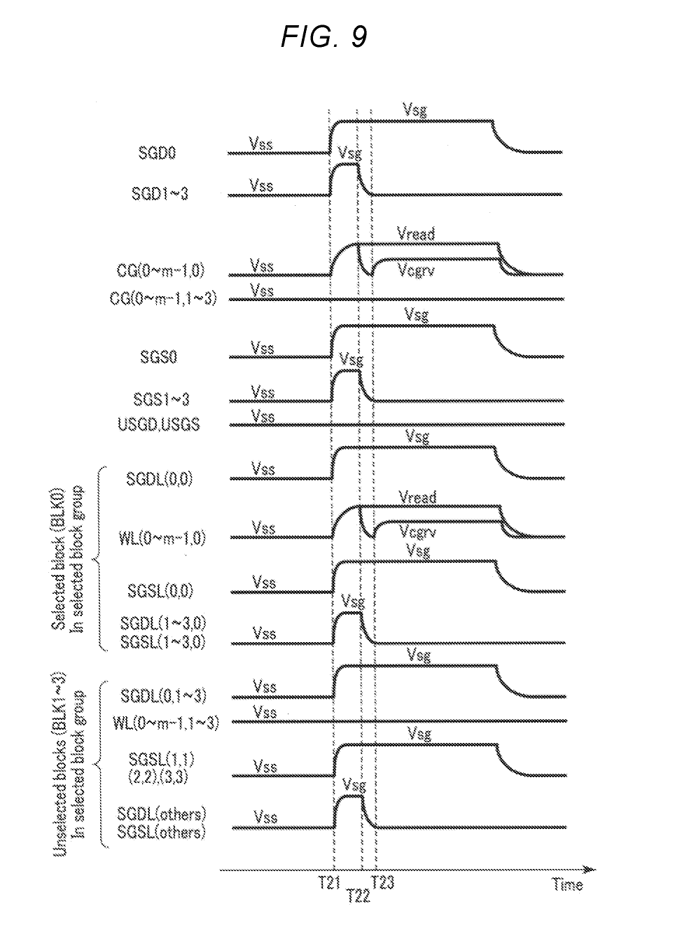

Next, a read operation of data of the semiconductor memory device according to the first embodiment will be described with reference to FIG. 9. FIG. 9 is a timing chart illustrating potential changes of various wires at the time of the read operation of data of the semiconductor memory device according to the first embodiment. In the following description, a case where data is read from a certain page of the string unit SU0 in the block BLK0 of the block group BG0 will be described.

Until reaching a point in time T21, the block decoder 15a outputs the block group select signal BLKSEL. That is, the transfer transistors TT10 to TT13, WT (0 to m−1, 0 to 3), and TT20 to TT23 in the transfer switch group 15b0 are in an ON state.

At the point in time T21, the select gate line driver applies a potential Vsg to the wires SGD0 and SGS0 corresponding to the selected string unit SU0. The potential Vsg has a magnitude which turns on the select transistors ST1 and ST2. In addition, the select gate line driver 12 temporarily applies the potential Vsg even to the wires SGD1 to SGD3 and SGS1 to SGS3 corresponding to the unselected string units SU1 to SU3. To apply the potential to the wires SGD and SGS, the potential Vsg is applied to all the select gate lines SGDL and SGSL in the block group BG0.

In addition, the word line driver 11 applies a potential Vread to the wires CG (0 to m−1, 0). That is, the potential Vread is applies to the word lines WL (0 to m−1, 0). The word line driver 11 maintains potentials of the wires CG (0 to m−1, 1 to 3) as the potential Vss, and retains the potential Vss in the word lines WL (0 to m−1, 1 to 3).

At a point in time T22, the select gate line driver 12 changes potentials of the wires SGD1 to SGD3 and SGS1 to SGS3 into the potential Vss. The select gate line driver 12 continuously applies the potential Vsg to the wires SGD0 and SGS0. That is, in the block group BG0, the potential Vsg is applied to only the select gate lines SGDL (0, 0) and SGSL (0, 0), and the potential Vss is applied to the other select gate lines SGDL and SGSL.

The select transistors ST1 of all the string units SU0 of the blocks BLK0 to BLK3 are turned on by the select gate line SGDL (0, 0) of the potential Vsg. Meanwhile, the select transistors ST2 in the string units SU0 of the blocks BLK0, the string units SU1 of the blocks BLK1, the string units SU2 of the blocks BLK2, and the string units SU3 of the blocks BLK3, are turned on by the select gate line SGSL (0, 0) of the potential Vsg. That is, both the select transistors ST1 and the select transistors ST2 are turned on in only the selected string unit SU0 of the selected block group BG0. As a result, only the selected string unit SU0 in the selected block group BG0 is connected between the bit lines BL and the source line CELSRC, and is in a selected state for a read operation.

Subsequently, at a point in time T23, the word line driver 11 changes a potential which is applied to the wire CG (p, 0) corresponding to the selected word line WL among the wires CG (0 to m−1, 0) into the potential Vss, and thereafter, applies a read potential Vcgrv. In addition, the word line driver 11 continuously applies the potential Vread to the wires CG corresponding to the unselected word lines WL. That is, the read potential Vcgrv is applied to the word line WL (p, 0) and the potential Vread is applied to the unselected word lines WL (0 to m−1 (≠p), 0), among the word lines WL (0 to m−1, 0). The read potential Vcgrv has a magnitude corresponding to data which is read, and the potential Vread has a magnitude which turns on the memory cell transistor MT regardless of retained data.

The word line driver 11 continuously applies the potential Vss to the wires CG (0 to m−1, 1 to 3) corresponding to each of the unselected blocks BLK0 to BLK3, and maintains the potential of the word lines WL (0 to m−1, 1 to 3) as the potential Vss.

In addition, the sense amplifier 16 senses and amplifies the data which is read through the bit line BL. Thereafter, the word line driver 11 changes the potential of all the wires CG (0 to m−1, 0 to 3) into the potential Vss, and terminates the read operation.

### 1.2.3 Erasure Operation

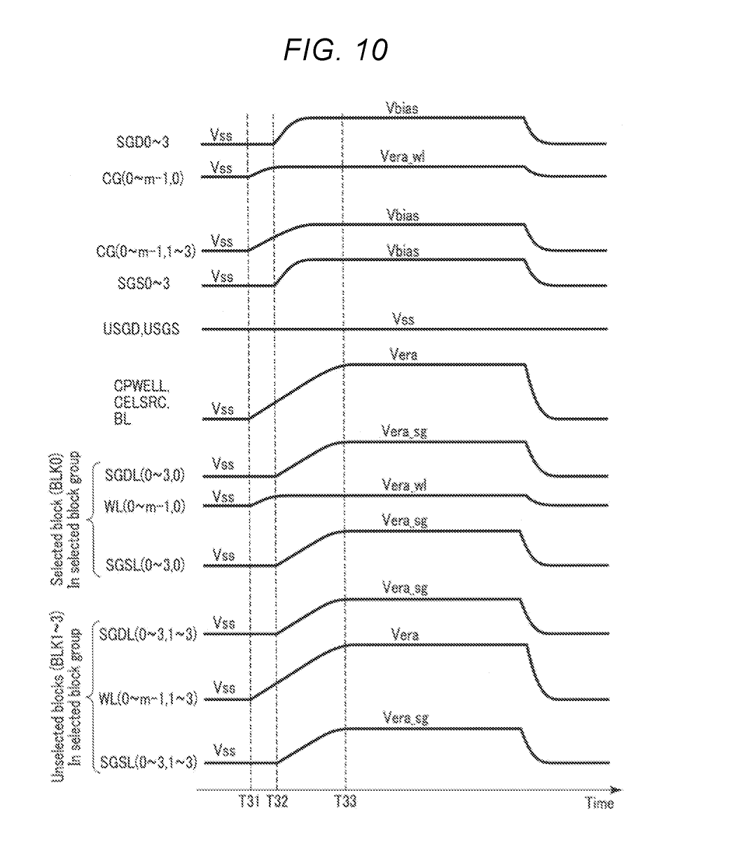

Next, an erasure operation of the semiconductor memory device according to the first embodiment will be described with reference to FIG. 10. FIG. 10 is a timing chart illustrating potential changes of various wires at the time of an erasure operation of data of the semiconductor memory device 1 according to the first embodiment. In the following description, a case where data of the block BLK0 in the block group BG0 is erased will be described.

Until reaching a point in time T31, the block decoder 15a0 corresponding to the block group BG0 outputs the block group select signal BLKSEL. That is, the transfer transistors TT10 to TT13, WT (0 to m−1, 0 to 3), and TT20 to TT23 in the transfer switch group 15b0 corresponding to the block group BG0 are in an ON state.

First, at the point in time T31, the source line driver 13, the well driver 14, and the sense amplifier 16 respectively starts raising potentials of the source line CELSRC, a well CPWELL, and the bit line BL to a potential Vera (for example, 20 V).

The word line driver 11 applies a voltage to the wires CG (0 to m−1, 0) corresponding to the selected block BLK0, and starts raising the potential to a potential Vera_wl (for example, 0.5V). The potential Vera_wl has a magnitude which maintains an ON state of the transfer transistors WT (0 to m−1, 0) having gates that receive the block group select signal BLKSEL. Thereby, potentials of the word lines WL (0 to m−1, 0) in the selected block BLK0 start rising to the potential Vera_wl. In addition, the potential Vera_wl has a magnitude to the extent that causes the erasure operation, in the memory cell transistor MT having a gate which receives the potential Vera_wl and a channel which receives the potential Vera. Accordingly, a potential of the word lines WL (0 to m−1, 0) in the selected block BLK0 is maintained as the low potential Vera_wl, as a result of which data is erased in the memory cell transistors MT having gates that receive the potential Vera_wl.

In addition, the word line driver 11 applies a voltage to the wires CG (0 to m−1, 1 to 3) corresponding to the unselected blocks BLK1 to BLK3, and start raising the voltage to a potential Vbias. The potential Vbias has a magnitude which turns on the transfer transistors WT (0 to m−1, 1 to 3) having gates that receive the block group select signal BLKSEL. Thereby, the potentials of the word lines WL (0 to m−1, 1 to 3) are maintained as the potential of each of the wires CG (0 to m−1, 1 to 3), and start rising to the potential Vbias. When the potential of the wires CG (0 to m−1, 1 to 3) reaches the potential Vbias, the transfer transistors WT (0 to m−1, 1 to 3) are respectively turned off, and the word lines WL (0 to m−1, 1 to 3) of the unselected blocks BLK1 to BLK3 respectively enter a floating state. The potential Vbias has a magnitude which does not cause the erasure operation, in the memory cell transistor MT having a gate that receive the potential Vbias and a channel whose potential is boosted to the potential Vera.

The select gate line driver 12 maintains potentials of all the wires SGD and SGS as the potential Vss until a point in time T32. That is, the potentials of all the select gate lines SGDL and SGSL are maintained as the potential Vss until the point in time T32.

Subsequently, at the point in time T32, the select gate line driver 12 applies a voltage to the wires SGD and SGS, and raises the voltage to the potential Vbias. That is, until the potentials of the wires SGD and SGS reach the potential Vbias, the potentials of the select gate lines SGDL and SGSL are maintained as the potential of the wires SGD and SGS. When the potentials of the wires SGD and SGS reach the potential Vbias, the transfer transistors TT1 and TT2 are turned off, and all the select gate lines SGDL and SGSL enter a floating state.

After the word lines WL (0 to m−1, 1 to 3) of the unselected blocks BLK1 to BLK3 and all the select gate lines SGDL and SGSL enter a floating state, the potential in the word lines WL (0 to m−1, 1 to 3) is raised by capacitance coupling due to a potential difference between channel regions in which channels are formed. Thereby, a potential difference between a charge storage layer and the channel region in the unselected block BLK1 to BLK3 is not generated, and data is not erased. Raising the potential is continued to a point in time T33 when raising the potentials of the bit line BL, the source line CELSRC, and the well CPWELL is completed. Here, since the potential of the word lines WL (0 to m−1, 1 to 3) is raised from the point in time T31, the potential is raised to the potential Vera. Meanwhile, since the potentials of the select gate lines SGDL and SGSL are raised from the point in time T32, the potentials are raised to a potential Vera_sg (for example, 17 V) lower than the potential Vera.

Thereafter, the sequencer 21 changes the potentials of all the wires into the potential Vss, and terminates the erasure operation.

### 1.3 Effects According to the Present Embodiment

According to the first embodiment, the number of transfer switches to the select gate lines can be reduced. The present effects will be described hereinafter.

A nonvolatile semiconductor memory device of a three-dimensional stack type includes multiple string units including multiple memory strings, in a block thereof. The multiple string units in the same block share word lines, and a voltage supplied to any one of the shared word lines is transferred by the same transfer transistor. Thereby, it is possible to reduce the number of transfer transistors and accordingly a chip size.

Meanwhile, in the write operation and read operation, a specified string unit in a certain specified block is selected, and thus, it is necessary to independently control a set of voltages of the select gate lines on a drain side and a source side, in each string unit. Accordingly, the required number of transfer transistors by which voltages are supplied to the select gate lines is twice the number of string units, and the effect of the number of transfer transistors on a chip size is relatively large. That is, reducing the number of transfer transistors relative to the number of select gate lines would reduce the chip size.

According to the configuration of the first embodiment, the semiconductor memory device 1 includes the four transfer transistors TT1 and the four transfer transistors TT2. Each of the four transfer transistors TT1 and the four transfer transistors TT2 is connected in common to a total of four string units SU, and each is selected according to which of the four string units SU is selected and which of the four blocks BLK is selected. Each of the four transfer transistors TT1 is connected to one and only one string unit SU in each of the four blocks BLK. Each of the four transfer transistors TT2 is connected to one and only one string unit SU in each of the four blocks BLK. In addition, a set of the four string units SU across the four blocks BLK which are selected by each of the four transfer transistors TT1 is different from a set of the four string units SU which are selected across the four blocks BLK by each of the four transfer transistors TT2. Accordingly, by a particular combination of one transfer transistor TT1 and one transfer transistor TT2, one string unit SU is uniquely selected. In addition, the transfer transistors UTT10 to UTT13 are connected to a set of the string units SU which are respectively connected to transfer transistors TT10 to TT13. The transfer transistors UTT20 to UTT23 are connected to a set of the string units SU which are respectively connected to transfer transistors TT20 to TT23. Accordingly, by a particular combination of one transfer transistor UTT1 and one transfer transistor UTT2, one string unit SU is uniquely selected. Thus, the number of transfer transistors TT1, TT2, UTT1, and UTT2 which are required for independently selecting the four blocks BLK that include the four string units SU, can be reduced to 16. In addition, the number of the wires SGD, SGS, USGD, and USGS which respectively connect the transfer transistors TT1, TT2, UTT1, and UTT2 to the select gate line driver 12, can be reduced to 10. Hence, it is possible to reduce the number of transfer transistors relative to the number of select gate lines.

In addition, according a first aspect of the first embodiment, each gate of the transfer transistors TT1, TT2, and WT is connected in common to the same wire. Thereby, the block group select signal BLKSEL can be shared by the multiple blocks BLK in the same block group BG. Hence, it is possible to not repeat the same configuration for each of the blocks in the same block group BG.

In addition, according to a second aspect of the first embodiment, multiple block groups BG are further included. The other terminals of the transfer transistors TT1, TT2, and WT in a certain block group BG, and the other terminals of the transfer transistors TT1, TT2, and WT in the other block groups BG are respectively connected in common to the wires SGD, SGS, and CG. Thereby, various wires between the word line driver 11 or the select gate line driver 12 and the transfer switch groups 15b can be shared between the multiple block groups BG. Hence, it is possible to not repeat the same configuration for each of the different block groups BG.

### 2. Second Embodiment

Next, a semiconductor memory device according to a second embodiment will be described. The semiconductor memory device according to the second embodiment provides for an additional sharing of wires between the memory cell array 10 and the row decoder 15 relative to the semiconductor memory device 1 according to the first embodiment. In the following description, the same symbols or reference numerals will be attached to the same elements as in the first embodiment, description thereof will be omitted, and only the elements different from those of the first embodiment will be described.

### 2.1 With Respect to Row Decoder and Peripheral Circuit

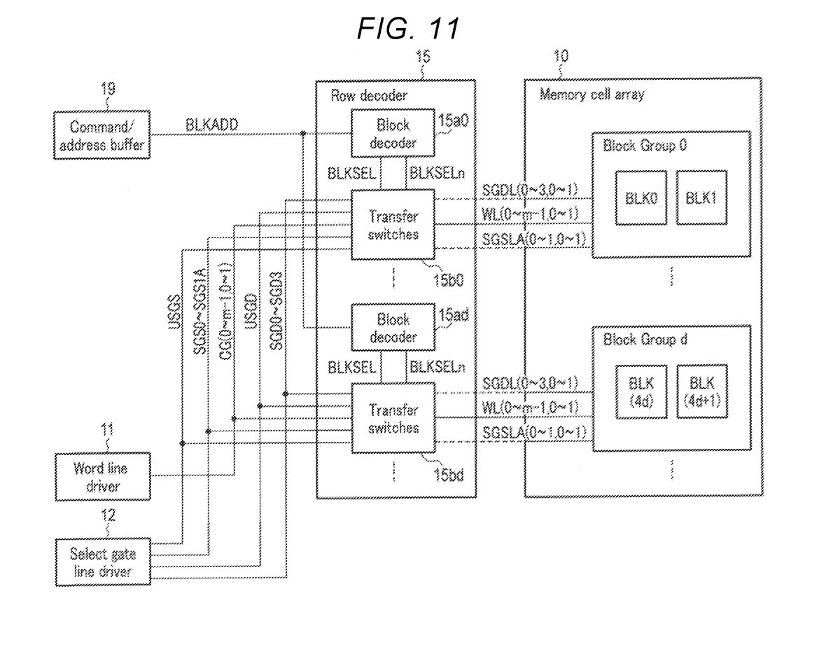

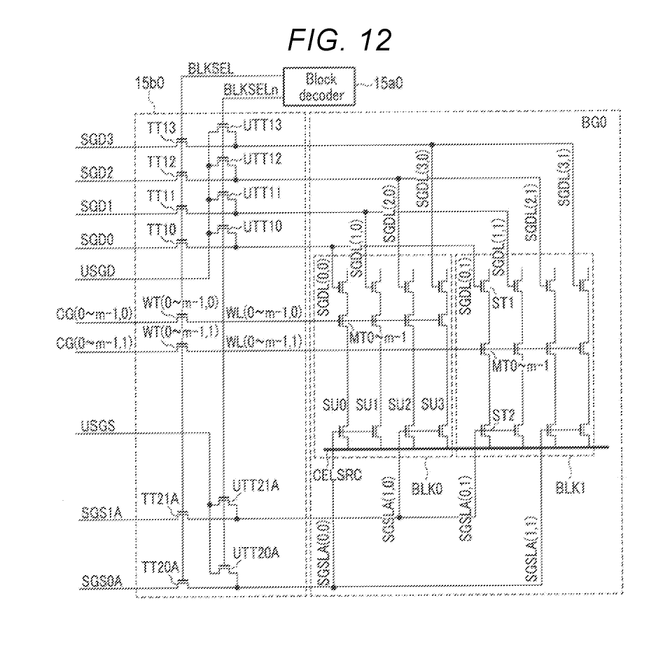

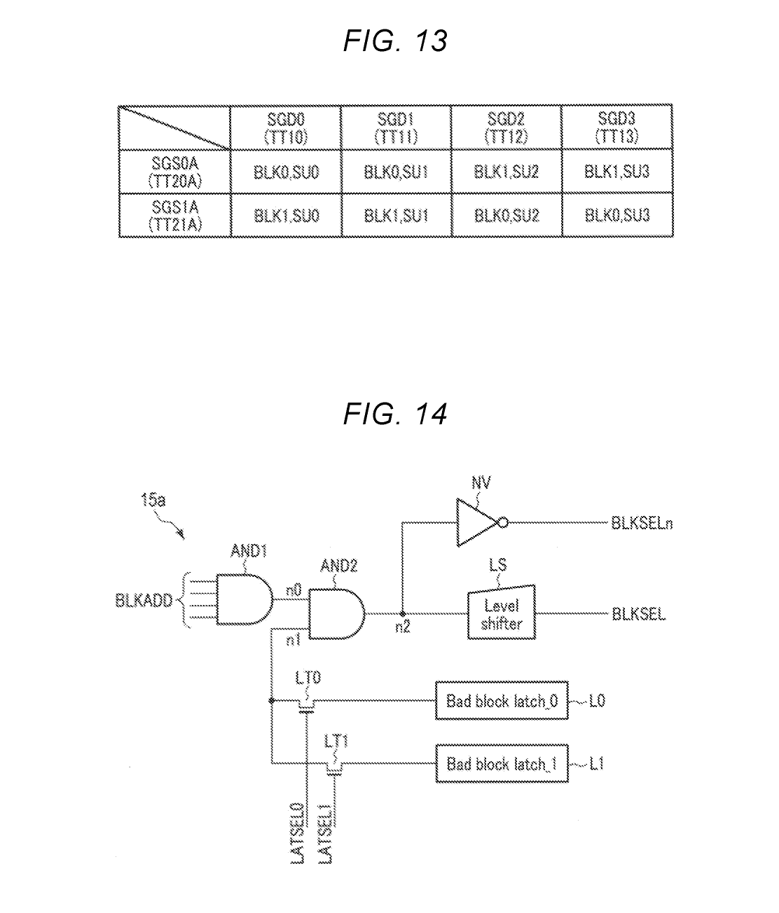

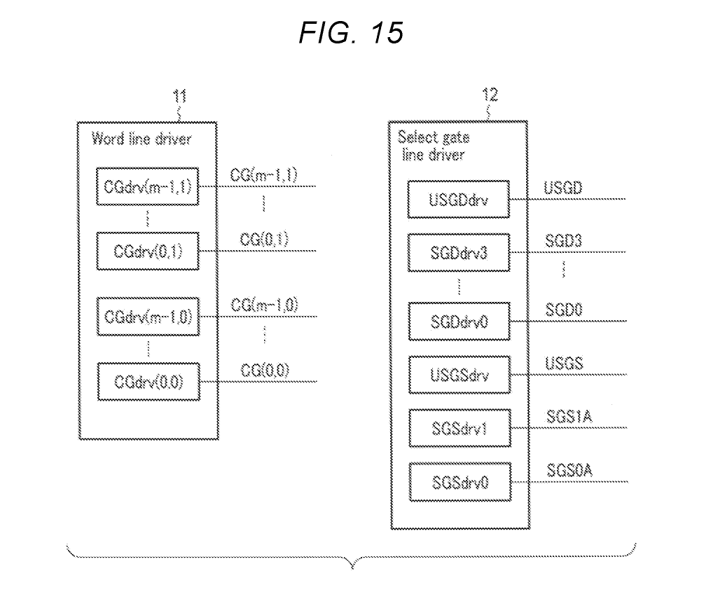

Configurations of a row decoder and a peripheral circuit in a semiconductor memory device according to a second embodiment will be described with reference to FIG. 11 to FIG. 15. FIG. 11 is a block diagram illustrating configurations of a row decoder 15 and a peripheral circuit in a semiconductor memory device 1 according to the second embodiment. FIG. 12 is a circuit diagram illustrating the configurations of the row decoder 15 and the peripheral circuit in the semiconductor memory device 1 according to the second embodiment. FIG. 13 is a table illustrating an example of block selection which is performed by the row decoder 15 of the semiconductor memory device 1 according to the second embodiment. FIG. 14 is a circuit diagram illustrating a configuration of a block decoder 15a of the semiconductor memory device 1 according to the second embodiment. FIG. 15 is a block diagram illustrating a configuration of a word line driver 11 and a select gate line driver 12 of the semiconductor memory device 1 according to the second embodiment.

As described in FIG. 11, each block group BG according to the second embodiment includes two blocks BLK. That is, a block decoder 15ad and a transfer switch group 15bd are shared by two blocks BLK4d and BLK4d+1 in a block group BGd. The number of blocks in the block group BG is not limited to two, and an arbitrary number of blocks BLK may be included therein. Here, in the second embodiment, it is required that the number of blocks in each block group BG is equal to or less than the number of string units which are connected in common to different select gate lines SGSLA among the string units included in each block BLK.

One terminal of each of the transfer switch groups 15b is connected in common to the select gate line driver 12 through the same wires USGD, USGS, SGD0 to SGD3, and SGSA (SGS0A to SGS1A). In addition, the other terminal of each of the transfer switch groups 15b is connected to one of the block groups BG which respectively correspond thereto, through select gate lines SGDL (0 to 3, 0 to 1), SGSLA (0 to 1, 0 to 1), and word lines WL (0 to m−1, 0 to 1).

A connection example of a block decoder 15a0, a transfer switch group 15b0, and a peripheral circuit is illustrated in FIG. 12, as a more specific example. As illustrated in FIG. 12, the transfer switch group 15b0 includes four transfer transistors TT1, 2m transfer transistors WT (0 to m−1, 0 to 1), and two transfer transistor TT2A (TT20A to TT21A) as transfer transistors for selecting the block group BG0. In addition, the transfer switch group 15b0 includes four transfer transistors UTT1 and two transfer transistor UTT2A (UTT20A to UTT21A) as transfer transistors for unselecting the block group BG0. That is, the transfer switch group 15b corresponding to a certain block group BG according to the second embodiment includes (2m+12) transfer transistors. Since the transfer transistors TT1, UTT1, and WT and the wires SGD, USGD, and CG connected thereto have the same configuration as in the first embodiment, description thereof will be omitted unless there is particular necessity.

Each gate of the transfer transistors TT1, WT, and TT2A receive in common the block group select signal BLKSEL from the block decoder 15a0. That is, the transfer transistors TT1, WT, and TT2A are turned on in a case where the block group select signal BLKSEL goes to an “H” level, and are turned off in a case where the block group select signal BLKSEL goes to an “L” level.

In addition, each gate of the transfer transistors UTT1 and UTT2A receive in common the block group select signal BLKSELn from the block decoder 15a0. That is, the transfer transistors UTT1 and UTT2A are turned on in a case where the block group select signal BLKSELn goes to an “H” level, and are turned off in a case where the block group select signal BLKSELn goes to an “L” level.

The select gate lines SGSLA are connected in common to gates of the select transistors ST2 of two string units SU in the block BLK. In addition, the select gate lines SGSLA are connected to wires SGSA through the transfer transistors TT2A. Specifically, the select gate lines SGSLA (0 to 1, 0) are connected in common to the wire SGS0A through the transfer transistor TT20A. The select gate lines SGSLA (0 to 1, 1) are connected in common to the wire SGS1A through the transfer transistor TT21A.

Each of the select gate lines SGSLA (0 to 1, 0) and SGSLA (0 to 1, 1) are connected in common to a wire USGS through the transfer transistors UTT20A and UTT21A, respectively.

That is, the wires CG, SGD, SGSA, USGD, and USGS according to the second embodiment include (2m+8) wires.

In summary of the above description, as illustrated in FIG. 13, a set of one wire SGD and one wire SGSA uniquely selects the string unit SU in the block groups BG. A set of one wire SGD and one wire SGSA corresponds to a set of one transfer transistor TT1 and one transfer transistor TT2A.

In addition, from another point of view, a connection relationship between each string unit SU of the block BLK and the wires SGD and SGSA in the block group BG0 is summarized as follows.

The string units SU0 to SU3 of the block BLK0 in the block group BG0 are respectively selected by a set of the wires SGD0 and SGS0A, a set of the wires SGD1 and SGS0A, a set of the wires SGD2 and SGS1A, and a set of the wires SGD3 and SGS1A.

The string units SU0 to SU3 of the block BLK1 are respectively selected by a set of the wires SGD0 and SGS1A, a set of the wires SGD1 and SGS1A, a set of the wires SGD2 and SGS0A, and a set of the wires SGD3 and SGS0A.

In the above configuration, a voltage which is applied to a set of one wire SGD and one wire SGSA is transferred to each gate of the select transistors ST1 and ST2 of one string unit SU in the selected block group BG. In addition, voltages which are applied to the wires CG are transferred to control gates of the memory cell transistors MT through the word lines in the selected block group BG.

Next, a configuration of the block decoder 15a of the semiconductor memory device according to the second embodiment will be described with reference to FIG. 14. As illustrated in FIG. 14, the block decoder 15a includes logical product circuits AND1 and AND2, bad block latches L0 and L1, an inverter NV, a level shifter LS, and latch select transistors LT0 and LT1.

The block decoder 15a according to the second embodiment is different from the block decoder 15a according to the first embodiment in that the number of the bad block latches L and the number of latch select transistors LT change depending on the number of blocks in the block group BG.

Next, configurations of the word line driver and the select gate line driver of the semiconductor memory device according to the second embodiment will be described with reference to FIG. 15. As illustrated in FIG. 15, the word line driver 11 includes drivers CGdrv (0 to m−1, 0 and 1). The select gate line driver 12 includes drivers SGDdrv0 to SGDdrv3, SGSdrv0 and SGSdrv1, USGDdrv, and USGSdrv. The drivers CGdrv, SGDdrv, SGSdrv, USGDdrv, and USGSdrv can respectively and independently output voltages.

The drivers SGSdrv0 and SGSdrv1 are respectively connected to the wires SGS0A and SGS1A. By connecting in this manner, independent voltages can be applied to each of total (2m+8) wires CG, SGD, SGSA, USGD, and USGS.

### 2.2 Effects of the Present Embodiment

According to the configuration of the second embodiment, the semiconductor memory device 1 includes the transfer transistors TT1 and TT2A. Each of the transfer transistors TT1 is connected in common to a total of two string units SU, and each is selected according to which of the four string units SU is selected and which of the two blocks BLK is selected. Each of the transfer transistors TT2A is connected in common to a total of four string units SU, and each is selected according to which of the four string units SU is selected and which of the two blocks BLK is selected. Each of the transfer transistors TT1 is connected to one and only one string unit SU in each of the two blocks BLK. Each of the transfer transistors TT2A is connected to two and only two string units SU in each of the two blocks BLK. In addition, the two string units SU which are selected by the transfer transistors TT1 are not both included in the four string units SU which are selected by the transfer transistors TT2A. Accordingly, by a particular combination of one transfer transistor TT1 and one transfer transistor TT2A, one string unit SU is uniquely selected. In addition, the transfer transistors UTT10 to UTT13 are connected to a set of the string units SU which are respectively connected to transfer transistors TT10 to TT13. The transfer transistors UTT20A and UTT21A are connected to a set of the string units SU which are respectively connected to transfer transistors TT20A and TT21A. Accordingly, by a particular combination of one transfer transistor UTT1 and one transfer transistor UTT2A, one string unit SU is uniquely selected. Thus, the number of transfer transistors TT1, TT2A, UTT1, and UTT2A which are required for independently selecting the two blocks BLK that include the four string units SU, can be reduced to 12. In addition, the number of the wires SGD, SGSA, USGD, and USGS which respectively connect the transfer transistors TT1, TT2A, UTT1, and UTT2A to the select gate line driver 12, can be reduced to 8. Hence, it is possible to reduce the number of transfer transistors relative to the number of select gate lines.

### 3. Modification Example or the Like

Embodiments are not limited to the aspects described in the first and second embodiments, and various modifications can be made. For example, in the first embodiment, an example is described in which the potential Vss (for example, 0 V) is applied to the word lines WL (0 to m−1, 1 to 3) which are respectively connected to the unselected blocks BLK1 to BLK3, at the time of a write operation. However, a potential (for example, a potential Vcelsrc which is the same as a potential of the source line CELSRC) higher than the potential Vss may be applied to the word lines WL (0 to m−1, 1 to 3). The case where the potential Vcelsrc is precharged in channel regions of unselected string units SU1 to SU3 in the block BLK0 until the write operation starts is assumed as an example.

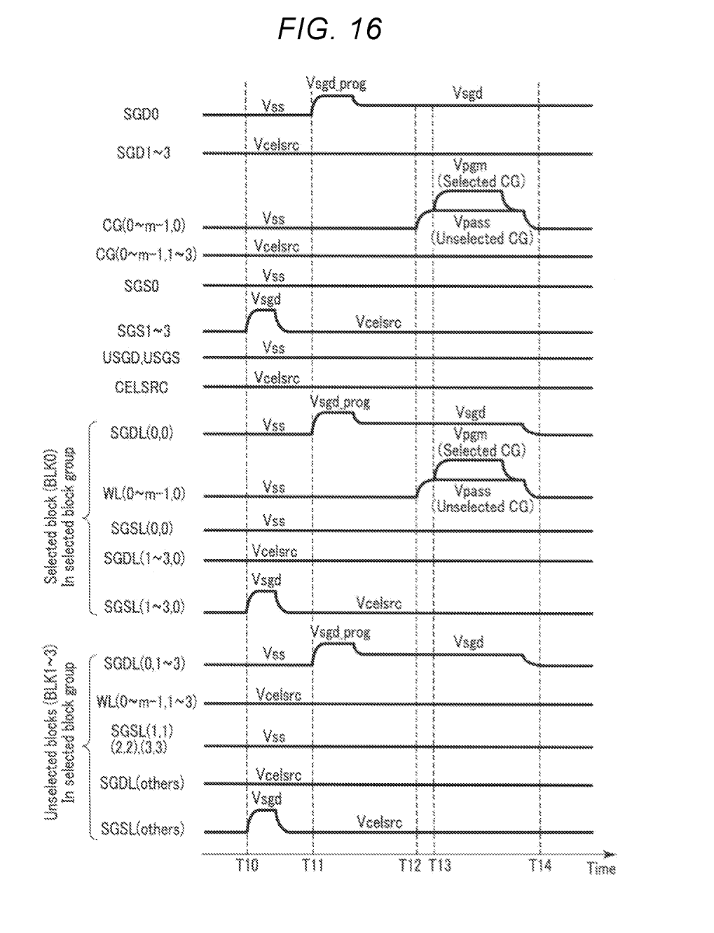

The above modification example will be described with reference to FIG. 16, based on a functional configuration of the semiconductor memory device 1 according to the first embodiment. FIG. 16 is a timing chart illustrating potential changes of various wires at the time of data program of a semiconductor memory device 1 according to a modification example of the first embodiment.

As illustrated in FIG. 16, at a point in time T10, the potential Vsgd is applied to the wires SGS1 to SGS3 which respectively correspond to the unselected string units SU1 to SU3 in the selected block BLK0. That is, the potential Vsgd is applied to all select gate lines SGSL except for the select gate lines SGSL (0, 0), SGSL (1, 1), SGSL (2, 2), and SGSL (3, 3) corresponding to the wires SGS0. Thus, the select transistors ST2 of each of the string units SU which are connected in common to the wires SGS1 to SGS3 are turned on. In addition, the potential Vcelsrc is applied to the source line CELSRC. By performing the operation in this manner, each channel of each string unit SU which is connected in common to the wires SGS1 to SGS3 is raised to the potential Vcelsrc.

Subsequently, the potential Vcelsrc is applied to all select gate lines SGSL except for the select gate lines SGSL (0, 0), SGSL (1, 1), SGSL (2, 2), and SGSL (3, 3) corresponding to the wires SGS0. By performing the operation in this manner, each of the string units SU which are connected in common to the wires SGS1 to SGS3 enters a floating state, in a state where a potential of the channel region is raised to the potential Vcelsrc.

In addition, the potential Vcelsrc is applied to the wires CG (0 to m−1, 1 to 3) corresponding to the unselected blocks BLK1 to BLK3. That is, the potential Vcelsrc is applied to the word lines WL (0 to m−1, 1 to 3) which respectively correspond to the wires CG (0 to m−1, 1 to 3). By performing the operation in this manner, when a program operation is performed, potentials of the control gates of the memory cell transistors MT in the string unit SU are maintained in the same magnitude as the potential of the channel region, in the unselected blocks BLK1 to BLK3.

Thereafter, the sequencer 21 performs a normal program operation after a point in time T11. A program operation after the point in time T11 is the same as in the first embodiment, and thus, description thereof will be omitted.

According to the modification example of the first embodiment, a potential which is equal to the potential of the channel regions of the unselected string units SU1 to SU3 in the selected block BLK0 is applied to the word lines WL (0 to m−1, 1 to 3) which are respectively connected to the unselected blocks BLK1 to BLK3. By performing the operation in this manner, it is possible to prevent unintended erasing of data from being performed in the unselected blocks BLK1 to BLK3, when the program operation is performed. More specifically, the potential of the channel regions of the unselected string units SU1 to SU3 in the selected block BLK0 is reliably coupled to a potential of the word lines WL (0 to m−1, 0) at the time of the program operation, and thus, the potential can be raised through the source line CELSRC. For example, the potential of the channel regions of the unselected string units SU1 to SU3 is applied the potential Vcelsrc higher than the potential Vss. That is, the potential of the channel regions of the string units SU in the unselected blocks BLK1 to BLK3 is in a state of being raised to the potential Vcelsrc, and when the program operation is performed, unintended erasing of data can be performed. Thus, by applying the potential Vcelsrc to the word lines WL (0 to m−1, 1 to 3) of the unselected blocks BLK1 to BLK3, a potential difference between the word lines WL (0 to m−1, 1 to 3) and the channel region is decreased, and unintended erasing of data can be prevented. Hence, it is possible to perform a more reliable write operation of data.

The present modification example is not limited to the first embodiment, and can also be employed in the second embodiment in the same manner as in the first embodiment.

In addition to this, the following processing can be employed in each embodiment.

In a multi-level read operation, a voltage which is applied to the word line that is selected in an A-level read operation is between 0 V and 0.55 V. The voltage is not limited to this, and may be between 0.1 V and 0.24 V, between 0.21 V and 0.31 V, between 0.31 V and 0.4 V, between 0.4 V and 0.5 V, or between 0.5 V and 0.55 V.

A voltage which is applied to the word line that is selected in a B-level read operation is between 1.5 V and 2.3 V. The voltage is not limited to this, and may be between 1.75 V and 1.8 V, between 1.8 V and 1.95 V, between 1.95 V and 2.1 V, or between 2.1 V and 2.3 V.

A voltage which is applied to the word line that is selected in a C-level read operation is between 3.0 V and 4.0 V. The voltage is not limited to this, and may be between 3.0 V and 3.2 V, between 3.2 V and 3.4 V, between 3.4 V and 3.5 V, between 3.5 V and 3.7 V, or between 3.7 V and 4.0 V.

Time (tR) of the read operation may be, for example, between 25 μs and 38 μs, between 38 μs and 70 μs, or between 70 μs and 80 μs.

A write operation includes a program operation and a verification operation. In the write operation, a voltage which is first applied to the word line that is selected at the time of program operation is, for example, between 13.7 V and 14.3 V. The voltage is not limited to this, and may be, for example, between 13.7 V and 14.0 V, or between 14.0 V and 14.7 V.

A voltage which is first applied to the word line that is selected when data is written to odd-numbered word lines may be changed with a voltage which is first applied to the word line that is selected when data is written to even-numbered word lines.

When the program operation is performed by using an incremental step pulse program (ISPP) method, it is recommended that, for example, approximately 0.5 V is used as a step-up voltage.

A voltage which is applied to an unselected word line may be, for example, between 7.0 V and 7.3 V. The voltage is not limited to this, and may be, for example, between 7.3 V and 8.4 V, or may be equal to or lower than 7.0 V.

A pass voltage which is applied may be changed depending on whether the unselected word lines are odd-numbered word lines or even-numbered word lines.

Time (tProg) of the write operation may be, for example, between 1,700 μs and 1,800 μs, between 1,800 μs and 1,900 μs, or between 1,900 μs and 2,000 μs.

In the erasure operation, a voltage that is first applied to a well which is formed on a semiconductor substrate and on which a memory cell is arranged is, for example, between 12 V and 13.7 V. The voltage is not limited to this case, and may be, for example, between 13.7 V and 14.8 V, between 14.8 V and 19.0 V, between 19.0 V and 19.8 V, or between 19.8 V and 21 V.

Time (tErase) of the erasure operation may be, for example, between 3,000 μs and 4,000 μs, between 4,000 μs and 5,000 μs, or between 5,000 μs and 9,000 μs.

The memory cell includes a charge storage layer which is arranged on the semiconductor substrate (silicon substrate) through a tunnel insulating film whose thickness is between 4 nm and 10 nm. The charge storage layer may have a stack structure of an insulating film such as an SiN film or an SiON film whose thickness is between 2 nm and 3 nm and polysilicon whose thickness is between 3 nm and 8 nm. In addition, a metal such as Ru may be added to the polysilicon. An insulating film is formed on the charge storage layer. The insulating film has a silicon oxide film whose thickness is between 4 nm and 10 nm which is interposed between a lower layer High-k film whose thickness is between 3 nm and 10 nm and an upper layer High-k film whose thickness is between 3 nm and 10 nm. HfO or the like can be used as the High-k films. In addition, the thickness of the silicon oxide film may be greater than the thickness of the High-k film. A control electrode whose thickness is between 30 nm and 70 nm is formed on the insulating film through a material whose thickness is between 3 nm and 10 nm. Here, such a material is a metal oxide film such as TaO, or a metal nitride film such as TaN. W or the like may be used as the control electrode.

In addition, an air gap can be formed between memory cells.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a plurality of string units, including first and second string units in a first block, third and fourth string units in a second block, each of the string units including a plurality of serially connected memory cells between first and second select transistors;
a first select gate line commonly connected to gates of the first select transistors of the first and third string units;
a second select gate line commonly connected to gates of the first select transistors of the second and fourth string units;
a third select gate line commonly connected to gates of the second select transistors of the first and fourth string units; and
a fourth select gate line commonly connected to gates of the second select transistors of the second string unit and another string unit.

2. The device according to claim 1, wherein the plurality of string units includes a fifth string unit in the second block and a sixth string unit in the first block, and the another string unit is the fifth string unit.

3. The device according to claim 2, further comprising:
a fifth select gate line commonly connected to gates of the second select transistors of the third and sixth string units.

4. The device according to claim 3, wherein the first, second, third, and fourth string units are selected by respectively applying a selection voltage to the first and third select gate lines, the second and fourth select gate lines, the first and fifth select gate lines, and the second and third select gate lines.

5. The device according to claim 1, wherein a total number of string units is N, which is 2 or more, and a total number of blocks is N.

6. The device according to claim 5, wherein a total number of select gate lines connected to gates of the first select transistors is N and a total number of select gate lines connected to gates of the second select transistors is N.

7. The device according to claim 1, wherein the another string unit is the third string unit.

8. The device according to claim 7, wherein the first, second, third, and fourth string units are selected by respectively applying a selection voltage to the first and third select gate lines, the second and fourth select gate lines, the first and fourth select gate lines, and the second and third select gate lines.

9. The device according to claim 8, wherein a total number of string units is N, which is an even number equal to 2 or more, and a total number of blocks is N/2.

10. The device according to claim 9, wherein a total number of select gate lines connected to gates of the first select transistors is N and a total number of select gate lines connected to gates of the second select transistors is N/2.

11. A semiconductor memory device, comprising:
M memory blocks, each of the memory blocks includes N string units, each of the string units including a plurality of serially connected memory cells between first and second select transistors; and
a row decoder for the M memory blocks, the row decoder including first transfer transistors that control voltages applied to first select gate lines connected to gates of the first transistors of the string units in the M memory blocks and second transfer transistors that control voltages applied to second select gate lines connected to gates of the second transistors of the string units in the M memory blocks,
wherein M is 2 or more and N is 4 or more, and a total number of the first and second transfer transistors is less than M×N.

12. The device according to claim 11, wherein the row decoder further includes third transfer transistors that control voltages applied to word lines connected to gates of the memory cells of the string units in the M memory blocks.

13. The device according to claim 12, wherein gates of the first, second, and third transfer transistors are connected to receive a block selection signal.

14. The device according to claim 11, wherein each of the first select gate lines is commonly connected to gates of at least two first select transistors of different string units across different memory blocks and each of the second select gate lines is commonly connected to gates of at least two second select transistors of different string units across different memory blocks.

15. The device according to claim 14, wherein each of the string units of the M memory blocks is uniquely selected, without selecting any of the other string units of the M memory blocks, by applying a selection voltage to one of the first select gate lines and one of the second select gate lines.

16. The device according to claim 11, wherein the total number of the first and second transfer transistors is M+N.

17. The device according to claim 11, wherein M is equal to N.

18. The device according to claim 17, wherein
each of the first select gate lines is commonly connected to gates of two first select transistors of two different string units across two different memory blocks and each of the second select gate lines is commonly connected to gates of two second select transistors of two different string units across two different memory blocks.

19. The device according to claim 11, wherein M is one-half N.

20. The device according to claim 11, wherein
each of the first select gate lines is commonly connected to gates of two first select transistors of two different string units across two different memory blocks and each of the second select gate lines is commonly connected to gates of four second select transistors of four different string units across two different memory blocks.
